(19) United States
(12) Patent Application Publication
(10) Pub. No.: US 2017/0012244 A1
(43) Pub. Date: Jan. 12, 2017

(54) ORGANIC ELECTROLUMINESCENT ELEMENT AND ILLUMINATION DEVICE

(71) Applicant: Panasonic Intellectual Property Management Co., Ltd., Osaka-shi (JP)

(72) Inventor: Jumpei MATSUZAKI, Hyogo (JP)

(73) Assignee: PANASONIC INTELLECTUAL PROPERTY MANAGEMENT CO., LTD., Osaka-shi (JP)

(21) Appl. No.: 15/115,093

(22) PCT Filed: Jan. 8, 2015
(86) PCT No.: PCT/JP2015/000066

§ 371 Date: Jul. 28, 2016

(30) Foreign Application Priority Data
Feb. 10, 2014 (JP) 2014-023445

(51) Int. Cl. H01L 51/52

(52) U.S. Cl. CPC H01L 51/5268; H01L 2251/5361

(57) ABSTRACT

This organic electroluminescent element includes: a substrate having light transmissivity; and an organic light emitting body including a first electrode, an organic light emitting layer, and a second electrode. The organic electroluminescent element includes a resin part which includes a first resin layer and a second resin layer between the substrate and the organic light emitting body. The resin part includes an uneven interface between the first resin layer and the second resin layer. The uneven interface includes a first uneven structure and a second uneven structure, and protrusions and recesses of the second uneven structure are smaller than protrusions and recesses of the first uneven structure. The second uneven structure has a random arrangement of the protrusions and recesses thereof.

### TECHNICAL FIELD

Organic electroluminescent elements and illumination devices including the same are disclosed.

### BACKGROUND ART

There has been generally known an organic electroluminescent element (hereinafter referred to as “organic EL element”) with a structure in which functional layers such as a hole injection layer, a hole transport layer, a light emitting layer, an electron transport layer, and an electron injection layer are stacked between an anode and a cathode provided on a light transmissive substrate. In this organic EL element, light is produced in the light emitting layer when voltage is applied between the anode and the cathode. The light produced in the light emitting layer is allowed to emerge outside through the electrode and the substrate which are light transmissive.

Light-outcoupling efficiency is important in organic EL elements. When light travels through an electrode and a substrate to the outside, the light may undergo total reflection and/or absorption. Therefore, it is generally difficult to allow a whole amount of the light produced to emerge outside. Accordingly, techniques for further improving the light-outcoupling efficiency have been developed.

JP 2007-242286 A discloses an organic EL element in which a scattering layer and a resistance reducing layer which have surface roughness are arranged on a substrate. However, even in the organic EL element employing the structure proposed by the above literature, it can hardly be said that a sufficient amount of light emitted from a light emitting layer emerges outside, and thus a further improvement in the light-outcoupling efficiency is in demand.

### SUMMARY OF INVENTION

The present disclosure aims to provide an organic electroluminescent element and an illumination device which have high light-outcoupling efficiency.

An organic electroluminescent element according to the present disclosure includes: a substrate having light transmissivity; an organic light emitting body including a first electrode, an organic light emitting layer and a second electrode; and a resin part which includes a first resin layer and a second resin layer and is disposed between the substrate and the organic light emitting body. The resin part includes an uneven interface between the first resin layer and the second resin layer. The uneven interface includes a first uneven structure and a second uneven structure, and protrusions and recesses of the second uneven structure are smaller than protrusions and recesses of the first uneven structure. The second uneven structure has a random arrangement of the protrusions and recesses thereof.

An illumination device according to the present disclosure includes the above organic electroluminescent element.

In the organic electroluminescent element according to the present disclosure, the uneven interface includes the relatively large first uneven structure and the fine second uneven structure, and thus light-outcoupling efficiency is high.

### BRIEF DESCRIPTION OF DRAWINGS

FIG. 1A is a schematic cross sectional view illustrating a layered structure of an organic electroluminescent element. FIG. 1B is a schematic cross sectional view illustrating an example of an uneven interface.

FIG. 2A is a schematic plan view illustrating a first uneven structure. FIG. 2B is a schematic cross sectional view illustrating the first uneven structure.

FIG. 3A is a plan view illustrating an example of patterning of the first uneven structure. FIG. 3B is a plan view illustrating an example of patterning of the first uneven structure.

FIG. 4A is an analysis diagram of the uneven interface. FIG. 4B is an analysis diagram of the uneven interface.

FIG. 5 is a graph illustrating a relationship between ten point mean roughness (Rz) and total luminous flux transmittance of a second uneven structure.

FIG. 6 is a graph illustrating a relationship between ten point mean roughness (Rz) and total luminous flux transmittance of the second uneven structure.

FIG. 7 is a schematic cross sectional view illustrating an example of an illumination device.

### DESCRIPTION OF EMBODIMENTS

An organic electroluminescent element (organic EL element) according to the present disclosure includes a substrate 1 having light transmissivity and an organic light emitting body 10. The organic light emitting body 10 includes a first electrode 3, an organic light emitting layer 4 and a second electrode 5. The organic EL element includes a resin part 2 which includes a first resin layer 21 and a second resin layer 22 and is disposed between the substrate 1 and the organic light emitting body 10. The resin part 2 includes an uneven interface 20 between the first resin layer 21 and the second resin layer 22. The uneven interface 20 includes a first uneven structure 2A and a second uneven structure 2B. Protrusions and recesses of the second uneven structure 2B are smaller than protrusions and recesses of the first uneven structure 2A. The second uneven structure 2B has a random arrangement of the protrusions and recesses thereof.

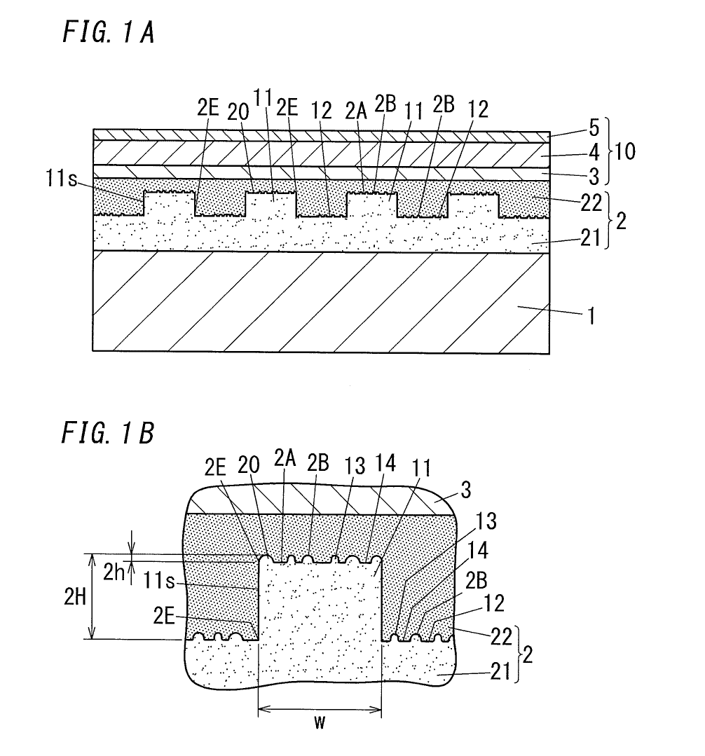

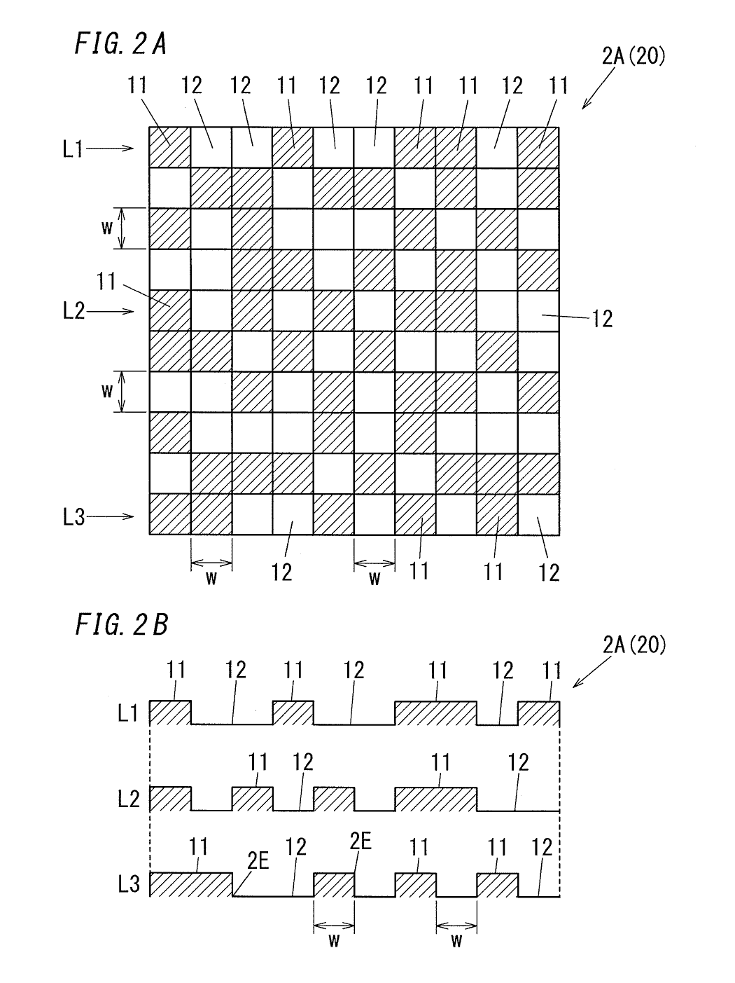

FIG. 1A and FIG. 1B show an example of the organic EL element. FIG. 1A illustrates a layered structure of the organic EL element, and FIG. 2B illustrates an enlarged part of the layered structure illustrated in FIG. 1A. FIG. 1A and FIG. 1B illustrate the layered structure of the organic EL element schematically, and thus thicknesses of layers, sizes and shapes of protrusions and recesses, and the like in an actual organic EL element may differ from those illustrated in FIG. 1A and FIG. 1B.

The substrate 1 has light transmissivity. As long as the substrate 1 transmits light, the substrate 1 may be transparent or translucent. Preferably, the substrate 1 is transparent. The substrate 1 may be of a glass substrate, a resin substrate, or the like. When the substrate 1 is of a glass substrate, since glass has low moisture permeability, moisture intrusion through the substrate 1 can be prevented. On the other hand, when the substrate 1 is of a resin substrate, the substrate 1 is unlikely to be shattered and scattered, leading to high safety and handleability.

The organic EL element may have a structure in which light emerges from the substrate 1. Such a structure is called as a bottom emission structure. As a matter of course, the organic EL element may have a double-side emission structure in which light can emerge from any of opposite sides of the organic EL element.

A surface of the substrate 1 opposite from the organic light emitting body 10 (light-outcoupling surface) may be provided with a light diffusing layer. The light diffusing layer can be formed by, for example, attaching an optical film. When the light diffusing layer is provided, more light can be allowed to emerge from the substrate 1. In addition, when light is diffused, color change depending on a viewing angle can be reduced.

The organic light emitting body 10 is a stack of the first electrode 3, the organic light emitting layer 4, and the second electrode 5. The organic light emitting body 10 may be defined as a structure in which the first electrode 3, the organic light emitting layer 4, and the second electrode 5 are stacked in a thickness direction. The organic light emitting body 10 is supported by the substrate 1. The organic light emitting body 10 may be formed on the substrate 1 as a base substrate.

The first electrode 3 is an electrode having light transmissivity. Furthermore, the second electrode 5 is an electrode paired with the first electrode 3. In one example of the organic EL element, the first electrode 3 may function as an anode, and the second electrode 5 may function as a cathode. In another example of the organic EL element, the first electrode 3 may function as a cathode, and the second electrode 5 may function as an anode. In short, as long as one of the pair of electrodes functions as an anode and the other of the pair of electrodes functions as a cathode, electricity can flow between the pair of electrodes. Since the first electrode 3 has light transmissivity, the first electrode 3 may function as an electrode disposed closer to a side of the organic EL element from which light emerges. In addition, the second electrode 5 may have light reflectivity. In this case, light emitted from the light emitting layer toward the second electrode 5 can be reflected by the second electrode 5 and then emerges from the substrate 1 to the outside. Alternatively, the second electrode 5 may be a light transmissive electrode. When the second electrode 5 is light transmissive, it is possible to employ a structure in which light emerges from a side opposite from the substrate 1 (back side). Additionally, when the second electrode 5 is light transmissive. a back surface of the second electrode 5 (a surface of the second electrode 5 opposite from the organic light emitting layer 4) may be provided with a light reflective layer, which makes it possible to reflect light traveling toward the second electrode 5 so that the light emerges from the substrate 1 to the outside. In this case, the light reflective layer may be scattering reflective or specular reflective.

The first electrode 3 may be made of transparent electrode material. For example, conductive metal oxide may preferably be used. Examples of conductive metal oxide include ITO, IZO, and AZO. The first electrode 3 may be formed by methods such as sputtering, vapor deposition, and coating. A thickness of the first electrode 3 is not particularly limited but, for example, may be within a range of 10 nm to 1000 nm.

The second electrode 5 may be made of appropriate electrode material. For example, the second electrode 5 may be formed of Al, Ag, or the like. The second electrode 5 may be formed by a method such as vapor deposition and sputtering. A thickness of the second electrode 5 is not particularly limited but, for example, may be within a range of 10 nm to 1000 nm.

The organic light emitting layer 4 has a function of generating light and generally includes a plurality of layers appropriately selected from a hole injection layer, a hole transport layer, a light emitting layer (a layer including light emitting dopants), an electron transport layer, an electron injection layer, an interlayer, and the like. A thickness of the organic light emitting layer 4 is not particularly limited but, for example, may be within a range of 60 to 300 nm.

When, for example, the first electrode 3 is an anode and the second electrode 5 is a cathode, a stack structure of the organic light emitting layer 4 may include, for example, a hole injection layer, a hole transport layer, a light emitting layer, an electron transport layer, and an electron injection layer which are arranged in this order from the first electrode 3. Note that, the stack structure is not limited to this and may be, for example: a single layer structure of a light emitting layer; a stack structure of a hole transport layer, a light emitting layer, and an electron transport layer; a stack structure of a hole transport layer and a light emitting layer; and a stack structure of a light emitting layer and an electron transport layer. Furthermore, the light emitting layer may have a single layer structure or a multilayered structure. For example, when a color of emitted light is white, the light emitting layer may be doped with three different colors, red, green, and blue, of dopant pigments, or red, green, and blue light emitting layers may be stacked. Furthermore, a light emitting unit may be defined as a stack structure which emits light when voltage is applied between the pair of electrodes with the stack structure situated therebetween. In this case, the organic EL element may have a multi-unit structure in which a plurality of light emitting units are stacked with (an) interlayer(s) having light transmissivity and conductivity in-between. A multi-unit structure is a structure including a plurality of light emitting units stacked in a thickness direction between the pair of electrodes (an anode and a cathode).

The organic EL element includes the resin part 2. The resin part 2 is made of resin. The resin part 2 may be in the form of a layer. The resin part 2 is disposed between the substrate 1 and the organic light emitting body 10. In the present embodiment, the resin part 2 adjoins the substrate 1. Also, the resin part 2 adjoins the first electrode 3.

The resin part 2 includes the first resin layer 21 and the second resin layer 22. The resin part 2 has a so-called double-layer structure. The resin part 2 includes the first resin layer 21 and the second resin layer 22 arranged in this order from the substrate 1. In the resin part 2, the first resin layer 21 is disposed closer to the substrate 1. The second resin layer 22 is disposed closer to the first electrode 3. The resin part 2 has light transmissivity. Accordingly, light emitted from the organic light emitting body 10 can emerge from the substrate 1. The first resin layer 21 may adjoin the substrate 1. The second resin layer 22 may adjoin the first electrode 3.

A refractive index of the second resin layer 22 is preferably different from a refractive index of the first resin layer. That is, the first resin layer 21 and the second resin layer 22 preferably have different refractive indices from each other. When the resin part 2 includes two resin layers having different refractive indices, more light emitted from the organic light emitting body 10 can emerge from the substrate 1. Note that, a refractive index is defined as a refractive index for a visible light wavelength. A representative wavelength of the visible light wavelength is, for example, 550 nm.

The resin part 2 includes the uneven interface 20. The uneven interface 20 is provided between the first resin layer 21 and the second resin layer 22. Due to the uneven interface 20, total reflection of light traveling from the organic light emitting body 10 to the substrate 1 is suppressed. The uneven interface 20 is an interface between the first resin layer 21 and the second resin layer 22. In an organic EL element, generally, there exists a difference (refractive index difference) between a refractive index of an organic layer which functions as the organic light emitting body 10 and a refractive index of the substrate 1, and total reflection occurs due to the refractive index difference. An organic layer is a layer which is included in the organic light emitting body 10 and contains one or more organic compounds. For example, the organic layer tends to have a higher refractive index than glass, and accordingly the refractive index of the organic layer tends to be higher than the refractive index of the substrate 1. In this case, some rays of total light traveling from the organic layer to the substrate 1 strike the substrate 1 at a high angle with respect to a direction perpendicular to a surface of the substrate 1 (the rays strike it obliquely). Such rays undergoes total reflection at the surface of the substrate 1 due to the refractive index difference when the angle is large. Thus, such rays have difficulty in entering the substrate 1. However, in a case where the uneven interface 20 is provided, light can be scattered by the uneven interface 20, and it is thus possible to allow more light with incident angles which otherwise cause total reflection to emerge from the substrate 1. Therefore, the light-outcoupling efficiency can be enhanced.

In the resin part 2, the uneven interface 20 can easily be formed at an interface between the two resin layers. When the resin part 2 includes the two layers, the uneven interface 20 is formed within the resin part 2, and thus it is possible to flatten both sides of the resin part 2. For example, if the layers are stacked on the substrate 1, the second resin layer 22 functions as a covering layer for the first resin layer 21 and thus give a flat surface over the protrusions and recesses, leading to stable formation of the organic light emitting body 10. Accordingly, disconnection failure and short circuit failure due to the protrusions and recesses can be suppressed. In addition, if the covering layer is provided, even when the uneven interface 20 with high (deep) protrusions and recesses is provided, the organic light emitting body 10 can be stacked and formed successfully. Therefore, the second resin layer 22 can function as a flat layer. In addition, since the two layers are transparent and have light transmissivity, light can emerge efficiently.

Either one of the refractive indices of the first resin layer 21 and the second resin layer 22 may be higher than the other. Since the uneven interface 20 is provided between the first resin layer 21 and the second resin layer 22, the light-outcoupling efficiency can be improved regardless of which of the two layers has the higher refractive index. In a preferable example, the refractive index of the second resin layer 22 is higher than the refractive index of the first resin layer 21. In this case, a resin layer with a high refractive index is disposed closer to the organic layer, and lead to a decrease in a refractive index difference between the organic layer and the adjacent resin layer. Therefore, more light can be made to strike the uneven interface 20 and thus more light can emerge outside. In this example, the first resin layer 21 is a low refractive index layer and the second resin layer 22 is a high refractive index layer. In this case, the term “low refractive index” and the term “high refractive index” each are used to only indicate which one of the resin layers is higher or lower than the other. Alternatively, the refractive index of the first resin layer 21 may be higher than the refractive index of the second resin layer 22. In this case, the layer having the higher refractive index is disposed closer to the substrate 1, and thus effects resulting from a refractive index difference between the substrate 1 and the organic layer can be adjusted.

In a preferable example, the refractive index of the second resin layer 22 is higher than the refractive index of the substrate 1. Accordingly, the effects resulting from the refractive index difference are reduced and thus the light-outcoupling efficiency can be enhanced. The refractive index of the second resin layer 22 is preferably higher than or equal to 1.75 for a visible light wavelength region. In this case, the effects resulting from the refractive index difference are further reduced and total reflection loss can be suppressed for a broader range of incident angels, leading to emergence of more light. The refractive index of the substrate 1 is, for example, within a range of 1.3 to 1.55. An upper limit of the refractive index of the second resin layer 22 is not particularly limited but, for example, may be 2.2 or 2.0. Furthermore, the refractive index difference between the second resin layer 22 and an adjacent layer which is the first electrode 3 is preferably small. For example, this refractive index difference may be smaller than or equal to 1.0.

In a preferable example, the refractive index of the first resin layer 21 is within a range of 1.3 to 1.52. Accordingly, more light can emerge outside. The refractive index difference between the first resin layer 21 and the substrate 1 is preferably small. For example, this refractive index difference may be smaller than or equal to 1.0. It is also preferable that the refractive index of the first resin layer 21 is lower than the refractive index of the substrate 1. In this case, total reflection can be suppressed at an interface between the first resin layer 21 and the substrate 1. As a matter of course, in the resin part 2, since scattering of light at the uneven interface 20 leads to an increase in emerging light, the refractive index of the first resin layer 21 may be higher than the refractive index of the substrate 1. The refractive index of the first resin layer 21 may be smaller than 1.5. In order to make the refractive index of the first resin layer 21 smaller than 1.5, for example, hollow nano particles may be added, or fluorine may be added in a molecular skeleton. It is preferable that the refractive indices of the substrate 1 and the first resin layer 21 are as small as possible. The closer the refractive indices of the substrate 1 and the first resin layer 21 becomes to the refractive index of air, which is 1, the less total reflection tends to occur at an interface between the substrate 1 and air. Lower limits of the refractive indices of the substrate 1 and the first resin layer 21 are ideally 1, but may be larger than 1.

The resin part 2 i.e., the first resin layer 21 and the second resin layer 22, is made of resin. Accordingly, the refractive indices can be easily adjusted, and formation of the protrusions and recesses and the flat surface over the protrusions and recesses can be easily performed. When resin materials are used, layers with relatively high refractive indices can be easily obtained. Furthermore, since a layer can be easily formed by applying resin, a layer having a flat surface can be more easily formed.

Examples of materials used for the first resin layer 21 and the second resin layer 22 include organic resin such as acrylic resin and epoxy resin. Examples of resin include ultraviolet curing resin and thermosetting resin. The resin is preferably ultraviolet curing resin. Ultraviolet curing resin does not need to be heated at all or needs to be heated only at a relatively low temperature in order to cure the resin, and thus heat history can be reduced. Furthermore, additives (such as a curing agent, a curing accelerator, and a curing initiator) to cure the resin can be added. The resin can have a high refractive index or a low refractive index by including particles to adjust the refractive index. For example, when the resin includes high refractive index particles such as metal oxides, a resin layer having a high refractive index can be formed. Further, for example, when the resin includes low refractive index particles such as particles having pores, a resin layer having a low refractive index can be formed. The two layers preferably have low light absorptivity. Accordingly, more light can emerge toward the substrate 1. An extinction coefficient of the resin layer is preferably as small as possible and ideally k=0 (or an unmeasurable value).

An interface between the second resin layer 22 and the first electrode 3 is preferably flat. The interface is given by an outer surface of the second resin layer 22. In a case where the second resin layer 22 covers the first resin layer 21, the outer surface of the second resin layer 22 can be made to be flat. When the outer surface is flat, the organic light emitting body 10 can be formed more stably, and short circuit failure and stacking failure can be suppressed.

The uneven interface 20 includes at least two kinds of uneven structures of different sizes. The two kinds of uneven structures included in the uneven interface 20 are defined as the first uneven structure 2A and the second uneven structure 2B. Since the uneven interface 20 includes the two kinds of uneven structures, more light can emerge outside.

The first uneven structure 2A has relatively large protrusions and recesses. The second uneven structure 2B has relatively fine protrusions and recesses. The protrusions and recesses of the second uneven structure 2B are smaller than the protrusions and recesses of the first uneven structure 2A. The protrusions and recesses of the first uneven structure 2A are larger than the protrusions and recesses of the second uneven structure 2B. Large or small protrusions and recesses may mean that protrusions and recesses with large or small size, respectively. The second uneven structure 2B may be called as a fine uneven structure. Also, the first uneven structure 2A may be called as a large uneven structure, and the second uneven structure 2B may be called as a small uneven structure. In this case, the term “large uneven structure” and the term “small uneven structure” each are used to only indicate which one of the first and second uneven structures 2A and 2B is larger or smaller than the other.

The first uneven structure 2A includes at least one protrusion 11 and at least one recess 12. The protrusion 11 of the first uneven structure 2A is a part of the first resin layer 21 protruded toward the organic light emitting body 10. The recess 12 of the first uneven structure 2A is a part of the first resin layer 21 recessed toward the substrate 1.

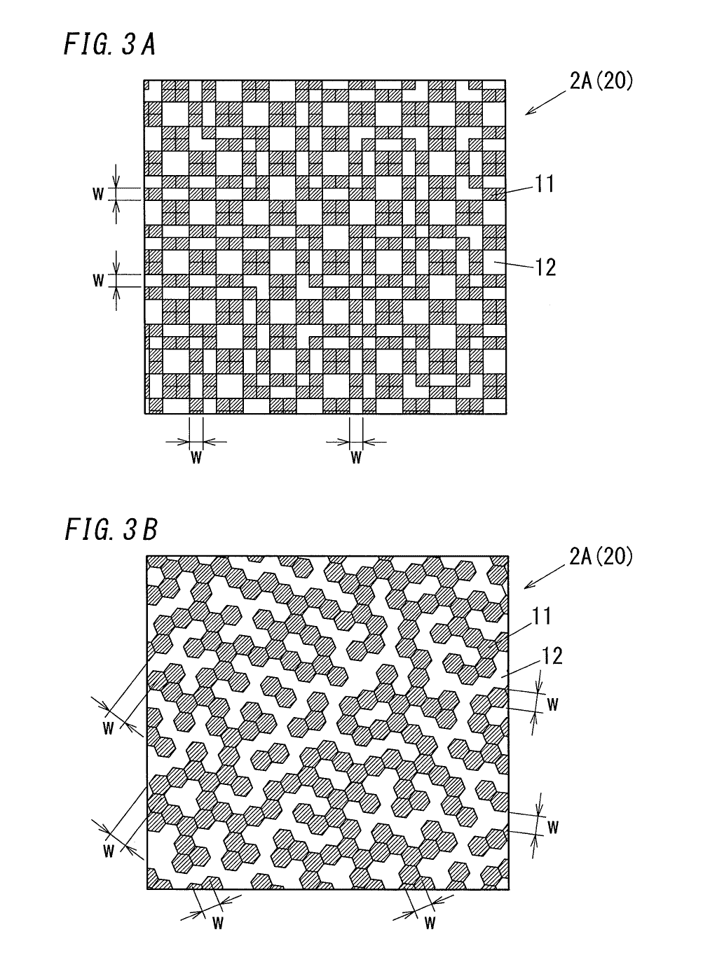

Sizes of the protrusions and recesses in the first uneven structure 2A are preferably within a range of 0.4 to 1.0 μm. The sizes of the protrusions and recesses may mean heights of the protrusions and recesses. The heights of the protrusions and recesses may mean lengths in a thickness direction from bottom parts of the recesses 12 (most recessed parts) to top parts of the protrusions 11 (most protruded parts). The thickness direction is a direction perpendicular to the surface of the substrate 1. When the sizes of the protrusions and recesses of the first uneven structure 2A lie within the above range, light can be scattered and thus more light can emerge toward the substrate 1. The heights of the protrusions and recesses of the first uneven structure 2A are represented as a height 2H in FIG. 1B. If positions of the bottom parts of the recesses 12 and the top parts of the protrusions 11 which are references for the heights are not substantially same with each other in the thickness direction, average positions in the thickness direction can be used as the references to determine the heights. Note that, in FIG. 2B, a width w of the protrusion 11 is illustrated. The width w will be explained further in the following when FIG. 2 and FIG. 3 are explained.

The protrusions and recesses of the second uneven structure 2B are fine protrusions and recesses. The sizes of the protrusions and recesses of the second uneven structure 2B are smaller than the sizes of the protrusions and recesses of the first uneven structure 2A. The second uneven structure 2B includes at least one protrusion 13 and at least one recess 14. The protrusion 13 of the second uneven structure 2B is a part of the first resin layer 21 protruded toward the organic light emitting body 10. The recess 14 of the second uneven structure 2B is a part of the first resin layer 21 recessed toward the substrate 1. The heights of the protrusions and recesses of the second uneven structure 2B are represented as a height 2h in FIG. 1B. If positions of the bottom parts of the recesses 14 and the top parts of the protrusions 13 are not substantially same with each other in the thickness direction, average positions in the thickness direction can be used as the references to determine the heights. The height 2h is smaller than the height 2H. The height 2h may be, for example, smaller than or equal to one fifth of the height 2H. The height 2h may be smaller than or equal to one tenth of the height 2H. The height 2h may be larger than or equal to one hundredth of the height 2H. The second uneven structure 2B may be a moss eye structure.

The second uneven structure 2B has a random arrangement of the protrusions and recesses. Accordingly, more light can emerge the outside. The random arrangement of the protrusions and recesses means that the protrusions 13 and the recesses 14 of the second uneven structure 2B are randomly arranged.

In the uneven interface 20, it can be said that the second uneven structure 2B is provided as the fine uneven structure on a surface of the first uneven structure 2A. Moreover, the second uneven structure 2B has the random arrangement of the protrusions and recesses. Since the uneven interface 20 has the relatively large first uneven structure 2A and the fine second uneven structure 2B, the light-outcoupling efficiency can be improved. Note that, in the resin part 2, light emitted from the organic light emitting body 10 emerges toward the substrate 1 by the uneven interface 20. In this case, since the first uneven structure 2A has the relatively large protrusions and recesses, the first uneven structure 2A scatters light. In particular, when the sizes of the protrusions and recesses of the first uneven structure 2A become closer to wavelengths in a visible light region, the light scattering property is enhanced. Accordingly, total reflection can be suppressed by scattering the light to change its direction of traveling, leading to emergence of more light toward the substrate 1. In addition, since the uneven interface 20 includes the second uneven structure 2B as the fine uneven structure, light can further emerge toward the substrate 1. Note that, in a case where the fine uneven structure is provided at the interface between the first resin layer 21 and the second resin layer 22, compared to a case where the fine uneven structure is not provided, an electric field at a boundary between the protrusion 11 and the recess 12 in the uneven interface 20 is disturbed, and thus imbalance in contour integrals of electric field vectors becomes large. In particular, in the uneven interface 20 having a steep edge, the electric filed close to the steep edge is disturbed and thus the imbalance in the contour integrals of the electric field vectors becomes even larger. As a result, light can emerge outside efficiently due to the uneven interface 20 and thus a more amount of the light striking the first resin layer 21 can be transformed into light striking the substrate 1. This is because the light reflected at the surface of the first resin layer 21 can emerge toward the substrate 1 without going through reflection and because a direction of the light traveling toward the substrate 1 can be changed so that the light has an incident angle which does not lead to total reflection at the substrate 1. Furthermore, since the second uneven structure 2B having the small protrusions and recesses is formed on a surface of the first uneven structure 2A having the large protrusions and recesses, a direction of traveling of light is changed by scattering at the first uneven structure 2A and the light can emerge efficiently due to the second uneven structure 2B. Due to scattering of light, even if the direction of light comes to have an incident angle such that the light cannot enter the first resin layer 21 and the substrate 1, evanescent can be disturbed at the fine uneven structure and thus the light can be transformed into light traveling toward the substrate 1. Due to this, the light-outcoupling efficiency can be effectively enhanced, compared to cases where only the first uneven structure 2A is provided and where only the second uneven structure 2B is provided.

The second uneven structure 2B has the random arrangement of the protrusions and recesses. It can also be said that the protrusions 13 and the recesses 14 of the second uneven structure 2B are randomly arranged. In the second uneven structure 2B, the arrangement of the protrusions 13 and the recesses 14 has no periodicity. The random arrangement of the protrusions and recesses enhances an evanescent disturbing effect. In addition, if the arrangement of the protrusions and recesses has periodicity, light having a certain wavelength or in a certain direction may emerge excessively or may not emerge. Therefore, it is preferable that the protrusions and recesses of the second uneven structure 2B are randomly formed. The randomness in the random arrangement of the protrusions and recesses of the second uneven structure 2B may be completely random.

In FIG. 1A and FIG. 1B, some parts of the second uneven structure 2B are disposed on surfaces of the protrusions 11 of the first uneven structure 2A, and remaining parts of the second uneven structure 2B are disposed on surfaces of the recesses 12 of the first uneven structure 2A. All parts of the second uneven structure 2B may be disposed on either the protrusions 11 or the recesses 12 of the first uneven structure 2A, but is preferably disposed on both of the protrusions 11 and the recesses 12. Accordingly, the evanescent disturbing effect can be more enhanced. Some parts of the second uneven structure 2B may be disposed on side surfaces 11s of the protrusions 11.

The first uneven structure 2A preferably includes the steep edge 2E at a boundary of each of the protrusions and recesses. The boundary of each of the protrusions and recesses means a boundary between the protrusion 11 and the recess 12. The steep edge may be a bent part of a surface. When the first uneven structure 2A includes the steep edge 2E, the light scattering property is enhanced. Accordingly, more light can emerge toward the substrate 1. Furthermore, when the first uneven structure 2A includes the steep edge 2E, the imbalance in the contour integral of the electric field vectors occurs at the steep edge 2E. The imbalance occurs even in light having an angle larger than a critical angle. Therefore, it is possible to transmit a part of energy of the light which undergoes total reflection from the second resin layer 22 to the first resin layer 21. Note that, if the uneven interface 20 includes the second uneven structure 2B as the fine uneven structure, evanescent generated at the steep edge 2E can be disturbed, and energy of light which undergoes total reflection can be reduced. Accordingly, light which otherwise undergoes total reflection is not reflected, and the light can enter the first resin layer 21 and travel toward the substrate 1. Furthermore, since evanescent tends to occur more at the steep edge 2E, a more component of light generated by evanescent (evanescent component) can emerge due to the second uneven structure 2B. Therefore, the light-outcoupling efficiency can be further enhanced.

In an example illustrated in FIG. 1A and FIG. 1B, the protrusions 11 of the first uneven structure 2A have tableland-like shapes. It can also be said that the recesses 12 have basin-like shapes. The side surface 11s of the protrusion 11 is parallel to the thickness direction. It can also be said that a side surface of the recess 12 is parallel to the thickness direction. Or, it can also be said that the boundary between the protrusion 11 and the recess 12 is parallel to the thickness direction. Some of the steep edges 2E are formed at top parts of the side surfaces 11s. Some of the steep edges 2E are formed at bottom parts of the side surfaces 11s. In short, the first uneven structure 2A has the step-like protrusions and recesses. Accordingly, the steep edge 2E is formed at the boundary of each of the protrusions and recesses.

The steep edge 2E of the first uneven structure 2A may be a square-corner-like part. Not a that, a tip of the steep edge 2E may be sharp, but the tip of the steep edge 2E does not need to be sharp and may be rounded. The steep edge 2E may be a part of the interface which bends at, for example, 120° or less. The steep edge 2E may be a flexure part.

The second uneven structure 2B preferably has ten point mean roughness Rz of larger than 100 nm and smaller than 200 nm. Accordingly, evanescent is disturbed and the effect such that light emerges from the substrate 1 can be enhanced. When ten point mean roughness Rz lies within the above range, generally, light having a wavelength in a visible light region tends not to be scattered. Due to that, the light-outcoupling efficiency tends not to be improved by scattering. However, when ten point mean roughness Rz of the second uneven structure 2B lies within the above range, evanescent tends to be disturbed by the protrusions and recesses which are smaller than a wavelength in a visible light region. For this reason, more light can emerge outside by providing the protrusions and recesses having different sizes. Ten point mean roughness Rz may be equal to the height 2h of the protrusions and recesses of the second uneven structure 2B.

At least one of the first resin layer 21 and the second resin layer 22 preferably includes particles. In this case, since the particles make it possible to form the fine protrusions and recesses, the second uneven structure 2B can be formed more easily. The particles may be used to form the fine protrusions and recesses. An average particle size of the particles is preferably smaller than the height 2H of the first uneven structure 2A. The average particle size of the particles is preferably smaller than or equal to a half of the height 2H of the first uneven structure 2A.

When the resin layer includes the particles, the sizes of the protrusions and recesses of the second uneven structure 2B are preferably larger than the particle sizes of the particles. In this case, since the second uneven structure 2B can be formed with the particles smaller than the protrusions and recesses of the second uneven structure 2B, the fine uneven structure can be formed efficiently. Moreover, when the particles are too large, general shapes of the protrusions and recesses and shapes of the fine protrusions and recesses may be negatively influenced. However, when the particles sizes of the particles for forming the protrusions and recesses are smaller than the protrusions and recesses of the second uneven structure 2B, the protrusions and recesses can be formed without negatively influencing the general shapes of the protrusions and recesses and the shapes of the fine protrusions and recesses. Accordingly, the light-outcoupling efficiency can be effectively improved.

The first resin layer 21 preferably includes the particles. When layers are stacked on the substrate 1, the fine protrusions and recesses can be easily formed by the particles included in the first resin layer 21. The particles included in the first resin layer 21 may have a function to adjust the refractive index. In this case, it becomes easier to form the first resin layer 21 with the adjusted refractive index, and thus the light-outcoupling efficiency can be more enhanced.

Furthermore, the particles may be included in both of the first resin layer 21 and the second resin layer 22. In this case, for example, the first resin layer 21 may include the particles to form the fine protrusions and recesses and the second resin layer 22 may include the particles to adjust the refractive index.

Note that, the second resin layer 22 may include the particles to form the fine protrusions and recesses. In this case, for example, when the resin part 2 is formed by pressing the second resin layer 22 against the first resin layer 21 or the resin part 2 is formed by stacking the second resin layer 22 and the first resin layer 21 in a reverse order, the fine protrusions and recesses can be formed with the particles included in the second resin layer 22. Moreover, when the resin part 2 is formed by transfer molding, the fine protrusions and recesses may be formed with the particles included in the second resin layer 22. Note that, in terms of easiness in manufacturing, it is preferably that the particles to form the fine protrusions and recesses are included in the first resin layer 21.

A resin layer which is one of the first resin layer 21 and the second resin layer 22 and includes the particles preferably includes the particles in a range of 20% by volume to 60% by volume. The particles included in the above range may be the particles for forming the fine protrusions and recesses. When the particles are included in the resin layer in the above range, the fine protrusions and recesses can be easily formed. When the first resin layer 21 includes the particles, the particles are preferable included in the first resin layer 21 in a range of 20% by volume to 60% by volume. In the resin layer, the particles are more preferably included in a range of 30% by volume to 50% by volume.

The particles included in the resin layer are preferably hollow particles which are substantially spherical. Accordingly, adjustment of the refractive index and formation of the protrusions and recesses can be performed efficiently. The hollow particles are preferably used especially in the resin layer which functions as the low refractive index layer. Since the particles are hollow, the refractive index can be easily lowered. For example, when the first resin layer 21 is provided as the low refractive index layer, the hollow particles make it possible to lower the refractive index of the first resin layer 21 as well as form the fine protrusions and recesses on the surface of the first resin layer 21. The hollow particles may be particles having pores. The hollow particles may be hollow beads. Moreover, the hollow particles may have shapes other than spherical shapes, but preferably have substantially spherical shapes. Examples of the shapes other than the spherical shapes may include rugby-ball shapes, elliptic shapes, and irregular rock shapes. When the hollow particles are substantially spherical, it becomes easier to form the protrusions and recesses larger than the sizes of the particles. It is speculated that this is due to flocculation of the particles. Therefore, when the substantially spherical particles are used, the fine uneven structure having high light-outcoupling efficiency can be efficiently formed. Hollow silica particles may be suitably used as the particles which are substantially spherical hollow beads.

The average particle size of the particles included in the resin layer is preferably smaller than 100 nm. Accordingly, the fine uneven structure can be efficiently formed. The particle sizes of the particles can be measured using, for example, a laser diffraction particle size distribution analyzer. The lower limit of the average particle size of the particles is not particularly limited, but may be, for example, larger than 1 nm. Accordingly, the particles can be obtained easily and handleability of the particles is improved. The particles having particle sizes within a range of 1 to 100 nm may be nano particles. It is easy to form the fine second uneven structure 2B with the nano particles. The nano particles may be called as nano microparticles. Resin materials where the nano particles are dispersed are suitably used to form the resin layer including the particles. As the particles, the nano particles which are hollow silica are suitably used.

It is preferable that the first uneven structure 2A has a structure in which the protrusion 11 or the recess 12 is allocated to each of predetermined sections. Accordingly, the scattering property of the first uneven structure 2A is enhanced and more light can emerge outside.

FIG. 2A and FIG. 2B are explanatory diagrams to explain an example of the first uneven structure 2A. In FIG. 2A and FIG. 2B, the allocation of the protrusion 11 and the recess 12 in the first uneven structure 2A is schematically illustrated. In FIG. 2A and FIG. 2B, the second uneven structure 2B is omitted. On the uneven interface 20, the first uneven structure 2A has a planar arrangement of the multiple protrusions 11 or the multiple recesses 12. A plane on which the multiple protrusions 11 or the multiple recesses 12 are arranged may be a plane parallel to the surface of the substrate 1. In FIG. 2A and FIG. 2B, the planar arrangement of the multiple protrusions 11 is illustrated. Also, it can be said that the planar arrangement of the multiple recesses 12 is illustrated. The first uneven structure 2A may have a structure which is the planar arrangement of the multiple protrusions 11 and the multiple recesses 12.

In the first uneven structure 2A, as illustrated in FIG. 2A and FIG. 2B, it is preferable that the multiple protrusions 11 or the multiple recesses 12 are arranged such that the protrusion 11 or the recess 12 which is of the size of each of lattice-like sections is allocated to one of the lattice-like sections. Accordingly, since the protrusions and recesses are formed with the protrusions 11 and the recesses 12 having the same size with each other, light can be scattered efficiently throughout the surface. The multiple protrusions 11 or the multiple recesses 12 are preferably arranged such that the protrusion 11 or the recess 12 which is of the size of each of the lattice-like sections is allocated randomly to one of the lattice-like sections. When the allocation is random, the light scattering property can be enhanced without angle dependency, and thus more light can emerge outside. Furthermore, when light emerges without angle dependency, viewing angle dependency can be reduced and thus light emission with less color change depending on a viewing angle can be obtained. In an example of the lattice-like sections, each section is a quadrangle. It is preferable that the quadrangle is a square. In this case, multiple quadrangles are arranged successively in rows and columns to form a matrix-like lattice (quadrangular lattice). In another example of the lattice-like sections, each section is a hexagon (see FIG. 3B). In this case, the hexagon is further preferably a regular hexagon. In this case, multiple hexagons are arranged in a filling structure to form a honeycomb lattice (hexagonal lattice). Note that, multiple triangles may be arranged to form a triangular lattice, but the quadrangular lattice or the hexagonal lattice are easier in controlling the protrusions and recesses.

The first uneven structure 2A illustrated in FIG. 2A and FIG. 2B has a planar arrangement of the multiple protrusions 11 having substantially same heights with each other in which one protrusion 11 is allocated to one of the matrix-like sections (the lattice-like sections), resulting in the protrusions and recesses in the matrix-like sections. Furthermore, in the first uneven structure 2A, when a unit region is defined as a region consisting of certain number of the lattice-like sections such that the multiple unit regions constitute the whole lattice-like sections, a ratio of a total area of the protrusions 11 in a unit region to a total area of the unit region in a plan view is substantially constant in all the unit regions constituting the whole lattice-like sections. Since this first uneven structure 2A is provided, the light-outcoupling efficiency can be efficiently improved.

With regard to the first uneven structure 2A illustrated in FIG. 2A and FIG. 2B, FIG. 2A illustrates the first uneven structure 2A in a direction perpendicular to the surface of the substrate 1, and FIG. 2B illustrates the first uneven structure 2A in a direction parallel to the surface of the substrate 1. In FIG. 2A, sections on which the protrusions 11 are allocated are illustrated with hatched lines. Lines L1, L2, and L3 in FIG. 2A corresponds to lines L1, L2, and L3 in FIG. 2B, respectively. In FIG. 2A and FIG. 2B, a width of each of the sections constituting the protrusions and recesses is denoted by w.

In the first uneven structure 2A illustrated in FIG. 2A and FIG. 2B, multiple squares are arranged successively in rows and columns (in a matrix) forming the matrix-like sections, and the protrusions 11 are allocated to some of the matrix-like sections, resulting in the protrusions and recesses in the matrix-like sections. Each of the matrix-like sections has the same area with each other. One of the protrusion 11 or the recess 12 is allocated to one section (one of the matrix-like sections). The protrusions 11 may be allocated regularly or irregularly. In the embodiment illustrated in FIG. 2A and FIG. 2B, the protrusions 11 are allocated randomly. As illustrated in FIG. 2B, in the section where the protrusion 11 is allocated, the part of the first uneven structure 2A is protruded toward the first electrode 3 to form the protrusion 11. Furthermore, the multiple protrusions 11 have substantially same heights with each other. Note that, the multiple protrusions 11 having substantially same heights with each other means, for example, when the heights of the protrusions 11 are averaged out, each of the multiple protrusions 11 has a height within a range of ±10% of the average height or preferably has a height within a range of ±5% of the average height.

In FIG. 2B, a cross sectional shape of the protrusion 11 is a rectangular shape, but may be an appropriate shape such as a corrugated shape, an inverted-triangle shape, and a trapezoidal shape. As mentioned earlier, the protrusion 11 preferably protrudes like a step. The protrusion 11 preferably has the steep edge. The recess 12 preferably has the steep edge. When at least two protrusions 11 are adjacent to each other, these protrusions 11 are connected integrally to form a larger protrusion 11. Furthermore, when at least two recesses 12 are adjacent to each other, these recesses 12 are connected integrally to form a larger recess 12. The number of connected protrusions 11 and the number of connected recesses 12 are not limited particularly. However, as these numbers increase, the scattering property of the first uneven structure 2A may be likely to lower. Therefore, the numbers may be appropriately set, for example, to be smaller than or equal to 100, 20, or 10. Note that, a design rule may be introduced such that when two or three or more recesses 12 or two or three or more protrusions 11 are continuously arranged, a region next to such continuous regions is set to correspond to the other of the recess 12 and the protrusion 11 (when the specific region is recessed, the next region is protruded, and when the specific region is protruded, the next region is recessed). When this rule is used, it is expected that the light scattering effect is improved and therefore the light-outcoupling efficiency can be improved.

The first uneven structure 2A is formed so that with regard to the unit regions consisting of the same number of the matrix-like sections, the ratio of the total area of the protrusions 11 in one of the unit regions to the total area of the unit region is substantially constant in all the unit regions constituting the whole matrix-like sections. For example, in FIG. 2A, one hundred sections are arranged in a 10 by 10 matrix manner. A region constituted by these one hundred sections may be used as a unit region. On the plane on which the uneven interface 20 is provided, the ratio of the total area of the protrusions 11 in one of the unit regions to the total area of the unit region is constant in any unit region. For example, as illustrated in FIG. 2A, when fifty protrusions 11 are provided to a unit region, about fifty (for example, forty-five to fifty-five or forty-eight to fifty-two) protrusions 11 may be provided to another unit region which consists of the same number of the matrix-like sections and has the same area as the unit region. A unit region is not limited to a region corresponding to one hundred sections, but may be a region having a size corresponding to an appropriate number of sections. For example, the number of sections defined as a unit region may be 1000, 10000, 1000000, or more. The ratio of the area of the protrusions 11 in a unit region to the total area of the unit region slightly varies depending on how to define the unit region. However, in this example, the ratios of the area of the protrusions 11 in a unit region to the total area of the unit region are set to be substantially same in all the unit regions. For example, a difference between each of upper and lower limits of the area ratio and an average of the area ratio is preferably equal to or less than 10% of the average ratio, and more preferably equal to or less than 5% of the average ratio, and further preferably equal to or less than 3% of the average ratio, and even further preferably equal to or less than 1% of the average ratio. As the area ratios in the unit regions become closer in values to each other, the light-outcoupling efficiency can be improved more evenly throughout the plane on which the uneven interface 20 is provided. The ratio of the area of the protrusions 11 in a unit region to the total area of the unit region is not limited particularly, but may be within a range of 20% to 80%, and preferably within a range of 30% to 70%, and more preferably within a range of 40% to 60%.

In a preferable example, the protrusions 11 or the recesses 12 are arranged randomly within each unit region. In this case, it is possible for more light to emerge outside without angle dependency. For example, in the organic EL element which emits white light, white light with less color change depending on an angel can be obtained.

In the first uneven structure 2A, the sizes of the protrusions and recesses in a plan view are substantially same as the heights of the protrusions and recesses. Accordingly, the light-outcoupling efficiency can be further improved. The sizes of the protrusions and recesses in a plan view may be same as the width w of the protrusion 11 or the recess 12. The heights of the protrusions 11 are, as described above, preferably within a range of 0.4 to 10 μm. Due to this, when, for example, each of the matrix-like sections is a square with a side of 0.1 to 100 μm, the first uneven structure 2A having the high scattering property can be formed. The side can be said to be the width w. In FIG. 3A, a length of the section is denoted as the width w. In addition, the side (width w) of the section constituting the matrix-like sections is more preferably within a range of 0.4 to 10 μm. Due to this, the heights and the widths of the protrusions and recesses of the first uneven structure 2A become closer, and thus the scattering property can be enhanced. For example, when the side of the section is 1 μm, the first uneven structure 2A can be formed accurately. Moreover, a unit region may be a square region of 1 mm×1 mm or a square region of 10 mm×10 mm.

Note that, when the sections are in hexagonal shapes as illustrated in FIG. 3B, the size of the section can be defined as a distance between two sides of the hexagon which are opposite each other. In FIG. 3B, a length of the section is denoted as the width w. When the sections are in hexagonal shapes, the protrusions and recesses of the first uneven structure 2A are arranged in a hexagonal lattice. The length (width w) of each section in the hexagonal lattice is preferably within a range of 0.1 to 100 μm and more preferably within a range of 0.4 to 10 μm.

By the way, in the first uneven structure 2A, the first resin layer 21 may be divided by the recesses 12. In this case, the first resin layer 21 has an island-like planar arrangement of the multiple protrusions 11 in which the multiple protrusion 11 are distributed like islands. For example, the second resin layer 22 may be in contact with the substrate 1 at the recesses 12.

The multiple protrusions 11 constituting the first uneven structure 2A may have similar or same shapes. In FIG. 2A, each of the protrusions 11 occupies entirely a corresponding one of the matrix-like sections, and the shapes of the protrusions 11 in a plan view are rectangular shapes (rectangle or square), but not limited thereto, and the planar shapes of the protrusions 11 may have shapes other than the rectangular shapes. For example, the shapes may be circular shapes or polygonal shapes (such as triangular shapes, pentagonal shapes, hexagonal shapes, and octagonal shapes). In this case, three dimensional shapes of the protrusions 11 may be appropriate shapes such as solid cylindrical shapes, prism shapes (such as triangular prism shapes and quadrangular prism shapes), and cone shapes (such as triangular cone shapes and quadrangular cone shapes). As illustrated in FIG. 2B, it is advantageous that the protrusion 11 and the recess 12 have the steep edge 2E.

The first uneven structure 2A may be formed as a diffraction optical structure. In this case, the protrusions 11 can be formed to show some degree of regularity to give the diffraction optical structure. In the diffraction optical structure, the protrusions 11 are further preferably formed periodically. When the resin part 2 has the diffraction optical structure, the light-outcoupling efficiency can be improved for certain kinds of light. Furthermore, when the resin part 2 has the diffraction optical structure, a light-outcoupling layer (such as an optical film) may be provided on a surface of the resin part 2 opposite from the substrate 1 to cause scattering of light, leading to decrease of influence by viewing angle dependency. In the diffraction optical structure, it is preferable that an interval P of the two dimensional protrusions and recesses (average interval of the protrusions and recesses in a case where the structure lacks periodicity) be appropriately set to be within a range of about λ/4 to about 100λ wherein λ is a wavelength of light in a medium (which is obtained by dividing a wavelength of light in vacuum by a refractive index of the medium). This range may be used in a case where a wavelength of light emitted from the light emitting layer is within a range of 300 to 800 nm. In this case, the light-outcoupling efficiency can be improved due to a geometrical optical effect, i.e. enlargement of an area of the surface which light strikes at an angle less than the total reflection angle, or due to light striking the surface at an angle not less than the total reflection angle which is emitted outside as diffraction light. In addition, when the interval P is set especially small (for example, within a range of λ/4 to λ), an effective refractive index around the uneven structure gradually decreases as becoming distant from the surface of the substrate. This is equivalent to interposing, between the substrate and a layer covering the uneven structure (the second resin layer 22) or between the substrate and the electrode (the first electrode 3), a thin film layer which has a refractive index between the refractive index of the medium of the uneven structure and the refractive index of the covering layer or the electrode. Consequently, it is possible to suppress Fresnel reflection. In other words, when the interval P is set within a range of λ/4 to 100λ, reflection (total reflection or Fresnel reflection) can be suppressed and thus the light outcoupling efficiency can be improved. Even in this range, when the interval P is smaller than λ, only the effects of suppressing Fresnel loss can be expected, and the light-outcoupling efficiency is likely to decrease. On the other hand, when the interval P is larger than 20λ, the heights of the protrusions and recesses need to become larger (in order to ensure a phase difference), and thus planarization by the covering layer (the second resin layer 22) is likely to become less easy. Using the covering layer having a quite large thickness (for example, larger than or equal to 10 μm) can be considered, but this method is disadvantageous due to unpreferable effects such as lowered transmittance, increased cost of materials, and increased outgas when resin materials are used. In view of this, the interval P is preferably set, for example, within a range of λ to 20λ.

The first uneven structure 2A may have a boundary diffraction structure. The boundary diffraction structure may be formed by, for example, randomly arranging the protrusions 11. Alternatively, the boundary diffraction structure may be a structure in which diffraction structures formed within very small regions of a plane are arranged all over the plane. In this case, it can be said that the structure is interpreted as a structure having a plurality of independent diffraction structures arranged in plane. In the boundary diffraction structure, diffraction caused by the fine diffraction structures can contribute to emergence of light to the outside and lowering angle dependency of light by suppressing light diffraction becoming too intense on the entire surface. Therefore, the light-outcoupling efficiency can be enhanced, suppressing angle dependency.

When the protrusions 11 and the recesses 12 are arranged completely randomly, if too many protrusions 11 or recessions 12 are arranged successively, the light-outcoupling efficiency might not be enhanced sufficiently. In view of this, it is preferable to set a rule defining that the number of same blocks (corresponding to one of the protrusion 11 and the recess 12) arranged continuously must not be greater than a predetermined number. In other words, it is preferable that the protrusions 11 are arranged so that the number of protrusions 11 arranged continuously in the same direction in the lattice-like sections is no greater than the predetermined number, and the recesses 12 are arranged so that the number of recesses 12 arranged continuously in the same direction in the lattice-like sections is no greater than the predetermined number. Consequently, the light-outcoupling efficiency can be more improved. Further, angle dependency of the color of the emitted light can be reduced. The predetermined number defining the maximum number of the protrusions 11 or the recesses 12 which are arranged continuously is preferably smaller than or equal to 10, and is more preferably smaller than or equal to 8, and is further preferably smaller than or equal to 5, and is further more preferably smaller than or equal to than 4. In such an arrangement, as a premise, the arrangement of the protrusions and recesses is random. However, randomness in the structure is controlled, and therefore such a structure can be defined as a controlled random structure. The boundary diffraction structure may be formed with controlled randomness.

FIG. 3A and FIG. 3B illustrate examples of the arrangement of the protrusions and recesses of the first uneven structure 2A. FIG. 3A illustrates an example in which sections to which the protrusions 11 or the recesses 12 are allocated are quadrangles. FIG. 3B illustrates an example in which sections to which the protrusions 11 or the recesses 12 are allocated are hexagons. In FIG. 3A and FIG. 3B, the first uneven structure 2A is controlled so that the arrangement of the protrusions 11 and the recesses 12 has randomness and that the number of same blocks (the protrusions 11 and the recesses 12) arranged continuously does not exceed a predetermined number. In FIG. 3A, more than two blocks are not arranged continuously in the same direction. In FIG. 3B, more than three blocks are not arranged continuously in the same direction. An average of the numbers of blocks arranged continuously can be expressed with an average pitch. Blocks are the protrusions 11 or the recesses 12 allocated to the sections. The average pitch can be expressed with the width w of a block. In the first uneven structure 2A illustrated in FIG. 3A, the structure is the quadrangular lattice and the average pitch is 3w. In the first uneven structure 2A illustrated in FIG. 3B, the structure is the hexagonal lattice and the average pitch is 3w. In FIG. 3A and FIG. 3B, a length of an axis of an ellipse or a diameter of a circle inscribed in the multiple protrusions 11 or the multiple recesses 12 in a direction perpendicular to the surface of the substrate 1 is preferably within a range of 0.4 to 4 μm. The uneven structure illustrated in FIG. 3A and FIG. 3B can be said to be the boundary diffraction structure.

In producing the organic EL element, the resin part 2 is formed on the substrate 1. In this case, the first resin layer 21 and the second resin layer 22 may be stacked in this order.

The first resin layer 21 and the second resin layer 22 may be formed on the surface of the substrate 1 by applying materials of the first resin layer 21 and the second resin layer 22. An appropriate coating method such as spin coating, screen printing, slit coating, bar coating, spray coating, and ink jet may be employed to apply the material depending on the use and the size of the substrate. After the application, the materials are cured to form the solidified resin layer. When the ultraviolet curing resin is used, the resin can be cured with irradiation of ultraviolet rays. When the thermosetting resin is used, the resin can be cured with heating.

The uneven interface 20 in the resin part 2 may be formed with an appropriate method. In the first uneven structure 2A, the protrusions and recesses are preferably formed by imprinting. Using imprinting, the protrusions and recesses having the sizes appropriate for the first uneven structure 2A can be formed efficiently and accurately. Moreover, when the protrusions and recesses are formed by allocating the protrusion 11 or the recess 12 to a section as described above, the protrusions and recesses can be formed accurately by imprinting. The steep edge 2E of the first uneven structure 2A can easily be formed using imprinting. When the protrusions and recesses are formed by imprinting, one section to which the protrusion 11 or the recess 12 is allocated may be one dot on which printing is performed. Alternately, one section may consist of multiple dots. It is preferable to use imprinting which can form the protrusions and recesses of the first uneven structure 2A, and for example, a method called nano imprinting can be employed.

Imprinting can be generally classified in to UV imprinting (also known as ultraviolet imprinting) and heat imprinting, and either one may be used. For example, UV imprinting is preferably used. Using UV imprinting, the protrusions and recesses of the first uneven structure 2A can be formed easily by printing (transferring) the protrusions and recesses. A transferring mold is used in UV imprinting. For example, a film mold which is formed by impressing of an Ni master mold patterned with a rectangular (pillar) structure of 2 μm in period and 1 μm in height is used. Then, UV curable imprint transparent resin (the material for the first resin layer 21) is applied onto the substrate and the mold is pressed against a resin surface of the substrate. Thereafter, the resin is irradiated with UV light (for example i-line with wavelength of λ=365 nm) which passes through the substrate or the film mold, in order to cure the resin. The mold is removed after the resin is cured. In this process, the mold is preferably subjected to treatment for facilitating removal (such as fluorine coating treatment) in advance so that the mold can be removed easily from the substrate. In this manner, the protrusions and recesses on the mold can be transferred to the resin layer. Note that, the mold has protrusions and recesses corresponding to the shape of the first uneven structure 2A. Thus, when the protrusions and recesses of the mold are transferred, the desired protrusions and recesses are provided to the surface of the resin layer. For example, when the mold in which the recessions are irregularly allocated to sections is used, it is possible to obtain the protrusions and recesses such that the protrusions 11 are randomly allocated, leading to the uneven surface of the first resin layer 21.

Note that, it is preferable that the particles are included in the material of the first resin layer 21. In this case, the particles make it possible to form the fine second uneven structure 2B on the surface of the first uneven structure 2A. In other words, when the particles are included in the first resin layer 21, the protrusions and recesses due to the particles are formed on the surface of the resin layer after the material of the first resin layer 21 is applied. Then, when the mold is pressed, the first uneven structure 2A is formed on the first resin layer 21 due to the protrusions and recesses of the mold, and at the same time the fine second uneven structure 2B is formed on the surface of the first resin layer 21 due to the particles included in the first resin layer 21. Since the second uneven structure 2B is formed by dispersion of the particles, the allocation of the protrusions and recesses can be random. Consequently, the uneven interface 20 including the two kinds of uneven structures can be formed efficiently. The average particle size of the particles for forming the second uneven structure 2B is, as described above, preferably in a range of 1 to 100 nm.

After the application of the material of the first resin layer 21 and formation of the uneven surface, the second resin layer 22 is applied. By applying the second resin layer 22, the uneven surface is disposed within the resin part 2. The surface of the second resin layer 22 is preferably flat. Since the uneven surface can be covered by application of the second resin layer 22, the resin part 2 with the flat surface can be easily formed.

Note that, when layers are stacked in a reverse order, it is preferable that the particles are included in the second resin layer 22. Also, the resin part 2 can be formed on another material in advance and then the resin part 2 may be transferred to the substrate 1. In this case, it is also preferred that the particles are included in the second resin layer 22 to form the fine second uneven structure 2B. Furthermore, the second uneven structure 2B can be formed also by pressing the material of the second resin layer 22 including the particles against the first resin layer 21 before the first resin layer 21 is completely cured. By the way, it is also possible to form the second uneven structure 2B by providing fine protrusions and recesses to the surface of the imprinting mold corresponding to the second uneven structure 2B and then by transferring the shapes of the fine protrusions and recesses. However, in this method of forming both of the first uneven structure 2A and the second uneven structure 2B by imprinting, it may become difficult to control the protrusions and recesses. In addition, it is not easy to form the first uneven structure 2A and the second uneven structure 2B accurately. Therefore, it is preferable to form the second uneven structure 2B with the particles.

In producing the organic EL element, the first electrode 3, the organic light emitting layer 4 and the second electrode 5 are stacked on the resin part 2. Stacking may be performed by an appropriate method selected from coating application, vapor deposition, sputtering, and the like. The first electrode 3, the organic light emitting layer 4 and the second electrode 5 are stacked to form the organic light emitting body 10. The organic light emitting body 10 is preferably enclosed and shielded from outside air. The organic light emitting body 10 may be enclosed by bonding an enclosing plate to the substrate 1.

As described above, the resin part 2 may be preferably formed as following. First, the material of the first resin layer 21 which is the resin including the particles is applied on the substrate 1, and then the protrusions and recesses are formed by imprinting. While this process, the first resin layer 21 may be uncured, half cured, or in a condition possible for transferring the shapes by imprinting. Due to this, the first uneven structure 2A is formed by the protrusions and recesses of an imprint. Moreover, the second uneven structure 2B is formed due to the particles. When the first resin layer 21 is still uncured or half cured, the solidified first resin layer 21 is formed preferably by curing the resin. The first resin layer 21 may be cured while the imprinting mold is pressed against the first resin layer 21. After that, the material of the second resin layer 22 is applied on the uneven surface of the first resin layer 21 and then the second resin layer 22 is cured to obtain the solidified second resin layer 22 which is the cured resin. As a matter of course, curing of the first resin layer 21 and curing of the second resin layer 22 may be performed simultaneously. Consequently the resin part 2 including the uneven interface 20 can be obtained.

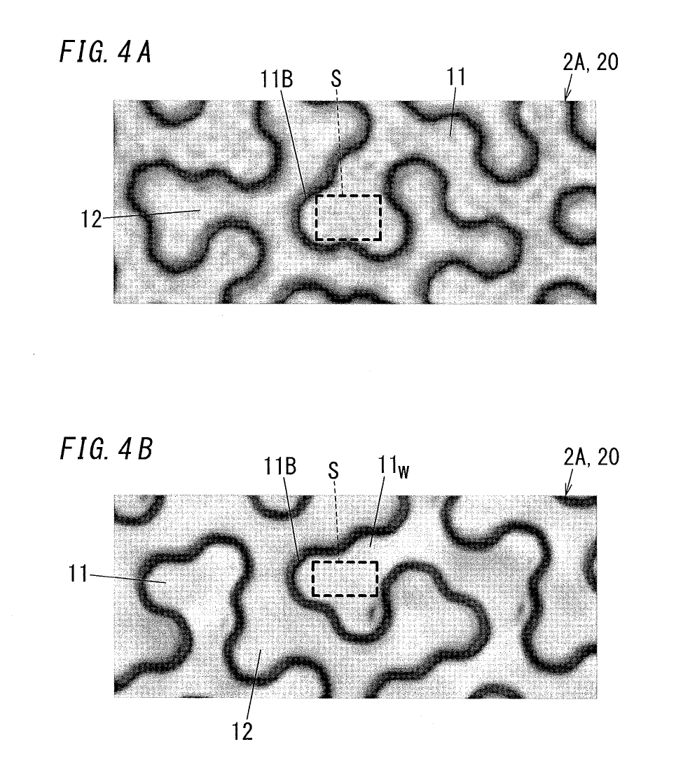

FIG. 4A and FIG. 4B illustrate analysis diagrams (pictures) of the uneven structure. Referring to FIG. 4A and FIG. 4B, an effect caused by the uneven interface 20 in the resin part 2 will be explained.

FIG. 4A illustrates the analysis of the uneven structure on the surface of the resin layer including the particles. FIG. 4B illustrates the analysis of the uneven structure on the surface of the resin layer not including the particles. These resin layers were formed as the first resin layer 21. In order to form these resin layers, the materials of the resin layers were applied on the substrates and the uneven surfaces were formed using UV nano imprinting. The analysis was performed with an electron microscope.

As illustrated in FIG. 4A and FIG. 4B, the boundary 11B between the protrusion 11 and the recess 12 in the first uneven structure 2A is observed as a part with a dark color. According to this, it is considered that the first uneven structure 2A has the steep edge. In FIG. 4A and FIG. 4B, the first uneven structure 2A is formed in the hexagonal lattice shape. The sections to which the protrusions or the recesses are allocated are hexagons. In FIG. 4A, shades are observed in a region of continuous protrusions 11 and a region of continuous recesses 12. Shades are expressed with shades of colors. On the other hand, in FIG. 4B, such shades are not observed. The shades are caused by the protrusions and recesses of the second uneven structure 2B. In FIG. 4A and FIG. 4B, the pattern of the protrusions and recesses of the first uneven structure 2A is the hexagonal lattice pattern of the protrusions and recesses illustrated in FIG. 3B. It can be understood from FIG. 4A and FIG. 4B that the first uneven structure 2A has the controlled random structure (boundary diffraction structure) such that the allocation of the protrusions 11 or the recesses 12 is random and at the same time more than three blocks of the protrusions 11 and the recesses 12 are not arranged continuously.

In FIG. 4A and FIG. 4B, a certain area of the protrusion 11 is selected as a measuring area S and then ten point mean roughness Rz of the measuring area S. In this manner, ten point mean roughness Rz of the second uneven structure 2B can be measured.

Furthermore, resin layers including the second uneven structures 2B with various ten point mean roughness Rz were formed by varying concentrations of the particles and the average particle size. Moreover, another resin layer (the second resin layer 22) was formed on each of the resin layers (the first resin layers 21) to obtain the resin part 2. Then, the organic EL element was produced using each resin part 2, and a relationship between ten point mean roughness Rz of each second uneven structure 2B and total luminous flux transmittance was investigated. The total luminous flux transmittance is defined as, when an interface is irradiated with rays of light at various angles, a ratio of a total amount of some of the rays of light passing through the interface to a total amount of the rays of light striking the interface.

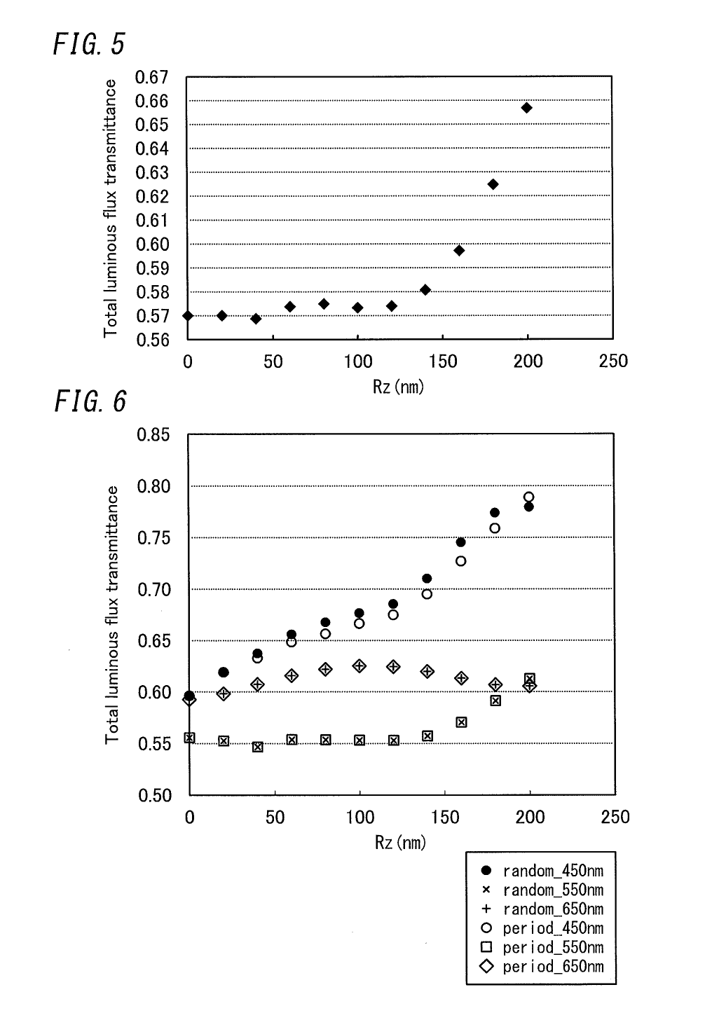

FIG. 5 is a graph illustrating a relationship between ten point mean roughness (Rz) of the second uneven structure 2B and total luminous flux transmittance. Light is visible light. As illustrated in the graph of FIG. 5, total luminous flux transmittance becomes high when ten point mean roughness Rz is larger than 100 nm. In other words, when ten point mean roughness Rz of the second uneven structure 2B is larger than 100 nm, in addition to the light scattering effect of the first uneven structure 2A, an effect of extracting the evanescent component can be obtained, and the light-outcoupling efficiency can be improved. It can be understood from the graph that ten point mean roughness Rz of the second uneven structure 2B is preferably larger than or equal to 130 nm, more preferably larger than or equal to 140 nm, and further preferably larger than or equal to 150 nm. As ten point mean roughness Rz becomes larger, total luminous flux transmittance increases. Note that, when ten point mean roughness Rz is larger than 200 nm, the sizes of the protrusions and recesses of the first uneven structure 2A and the sizes of the protrusions and recesses of the second uneven structure 2B become close, and it may become difficult to gain desired light-outcoupling effect. Therefore, ten point mean roughness Rz is preferable smaller than 200 nm.

FIG. 6 is a graph illustrating a relationship between ten point mean roughness (Rz) of the second uneven structure 2B and total luminous flux transmittance determined in the same manner as in FIG. 5. FIG. 6 illustrates a relationship between ten point mean roughness (Rz) and total luminous flux transmittance with regard to light having a wavelength of 450 nm, light having a wavelength of 550 nm, and light having a wavelength of 650 nm. Light having a wavelength of 450 nm may be blue light. Light having a wavelength of 550 nm may be green light. Light having a wavelength of 650 nm may be red light. Light of various colors may be produced by mixing blue light, green light, and red light. In particular, white light can be produced. In addition, the graph of FIG. 6 illustrates results of a case where the protrusions and recesses of the second uneven structure 2B are randomly arranged and a case where the protrusions and recesses of the second uneven structure 2B are periodically arranged. Depending on the arrangement of the particles or the shapes of the fine protrusions and recesses of the mold, it is possible to randomly or periodically arrange the protrusions and recesses of the second uneven structure 2B.

As illustrated in FIG. 6, whether the protrusions and recesses of the second uneven structure 2B are arranged randomly or periodically does not exert much influence on a relationship between ten point mean roughness (Rz) and total luminous flux transmittance for light having a wavelength of 550 nm and light having a wavelength of 650 nm. However, for light having a wavelength of 450 nm, total luminous flux transmittance is larger in a case where the protrusions and recesses of the second uneven structure 2B are arranged randomly than arranged periodically. Therefore, in the second uneven structure 2B, it is advantageous to arrange the protrusions and recesses randomly. Note that, blue light tends to influence the luminance magnitude more, and thus an observer feels as if more light is emitted when more blue light emerges. Therefore, the random arrangement of the protrusions and recesses of the second uneven structure 2B makes it possible to increase the feeling luminance magnitude as well as to improve light outcoupling efficiency.

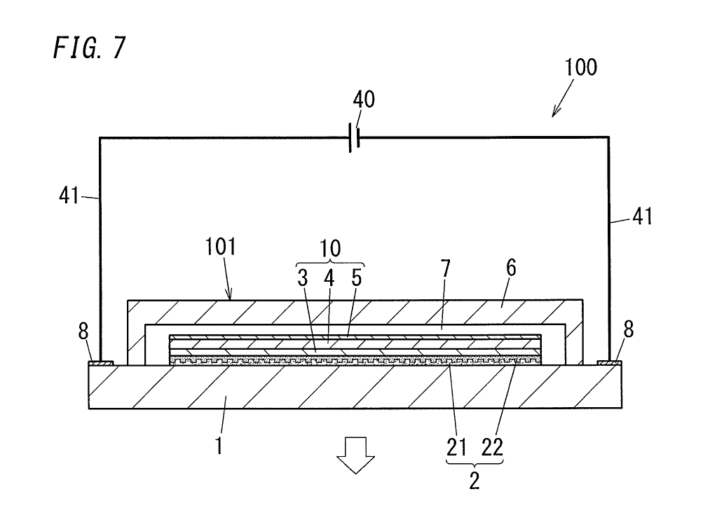

FIG. 7 illustrates an example of the illumination device 100 including the organic electroluminescent element (the organic EL element 101). The organic EL element 101 includes the substrate 1, the resin part 2, the first electrode 3, the organic light emitting layer 4, the second electrode 5, and the enclosing plate 6. The resin part 2 includes the first resin layer 21 and the second resin layer 22. A housing space 7 to house the organic light emitting body 10 is provided between the substrate 1 and the enclosing plate 6. The housing space 7 may be hollow or may be filled with a filler. A direction to which light is emitted is denoted with an outlined arrow. The illumination device 100 includes the organic EL element 101 and at least one electrode pad 8 formed outside an enclosed part of the organic EL element 101. The electrode pad 8 and the electrode of the organic EL element 101 are electrically interconnected by an appropriate wiring structure. The electrode pad 8 is connected with a wiring 41. The illumination device 100 may include the wiring 41. The illumination device may include a plug integrated with the wiring 41. The wiring 41 may be connected with an external power supply 40 through an external wiring. When the wiring 41 is connected with the external power supply 40, electricity flows between the electrodes and the organic light emitting body 10 emits light. Consequently, light is emitted from the illumination device 100.

1. An organic electroluminescent element comprising:
a substrate having light transmissivity;
an organic light emitting body including a first electrode, an organic light emitting layer and a second electrode; and
a resin part which includes a first resin layer and a second resin layer and is disposed between the substrate and the organic light emitting body,
the resin part including an uneven interface between the first resin layer and the second resin layer,
the uneven interface including a first uneven structure and a second uneven structure,
protrusions and recesses of the second uneven structure being smaller than protrusions and recesses of the first uneven structure,
the second uneven structure having a random arrangement of the protrusions and recesses thereof
ten point mean roughness Rz of the second uneven structure being larger than 100 nm and smaller than 200 nm, and
heights of the protrusions and recesses of the first uneven structure being 0.4 to 10 μm.

2. The organic electroluminescent element according to claim 1, wherein
each of the protrusions and recesses of the first uneven structure includes a steep edge at a boundary thereof.

3. (canceled)

4. The organic electroluminescent element according to claim 1, wherein:
at least one of the first resin layer and the second resin layer contains particles; and
sizes of the protrusions and recesses of the second uneven structure are larger than particle sizes of the particles.

5. The organic electroluminescent element according to claim 4, wherein
a percentage by volume of the particles of the at least one of the first and second resin layers containing the particles is in a range of 20 to 60 vol %.

6. The organic electroluminescent element according to claim 4, wherein
the particles are hollow particles which are substantially spherical.

7. The organic electroluminescent element according to claim 4, wherein
an average particle size of the particles is smaller than 100 nm.

8. The organic electroluminescent element according to claim 1, wherein
the first uneven structure has a structure in which a protrusion or a recess is allocated to each of predetermined sections.

9. The organic electroluminescent element according to claim 8, wherein
the protrusion or the recess is randomly allocated to each of the predetermined sections.

10. An illumination device comprising:
the organic electroluminescent element according to claim 1; and
a wiring.
